(19) United States
(12) Patent Application Publication
(10) Pub. No.: US 2009/0278578 A1
(43) Pub. Date: Nov. 12, 2009

(54) DELAY LOCKED LOOP CIRCUIT AND DELAY LOCKING METHOD

(75) Inventors: Yong-Ju Kim, Ichon (KR); Sung-Woo Han, Ichon (KR); Hee-Woong Song, Ichon (KR); Ic-Su Oh, Ichon (KR); Hyung-Soo Kim, Ichon (KR); Tae-Jin Hwang, Ichon (KR); Hae-Rang Choi, Ichon (KR); Ji-Wang Lee, Ichon (KR); Jae-Min Jang, Ichon (KR); Chang-Kun Park, Ichon (KR)

Correspondence Address: BAKER & MCKENZIE LLP;PATENT DEPARTMENT, 2001 ROSS AVENUE, SUITE 2300, DALLAS, TX, 75201, US

(73) Assignee: HYNIX SEMICONDUCTOR, INC., Ichon (KR)

(21) Appl. No.: 12/332,295

(22) Filed: Dec. 10, 2008

(30) Foreign Application Priority Data
May 8, 2008 (KR) 10-2008-0043023

(51) Int. Cl. H03L 7/06

(52) U.S. Cl. 327/149

(57) ABSTRACT

A delay locked loop circuit includes a phase detecting unit for detecting a phase difference between a reference clock signal and a feedback clock signal, and for producing a phase difference detection signal, a code generating unit for producing a digital code signal according to the phase difference detection signal, a control current generating unit for generating a control current using the digital code signal, and a current controlled delay line for producing the feedback clock signal by delaying the reference clock signal by a delay time varied by the control current.

### CROSS-REFERENCES TO RELATED APPLICATION

The present application claims priority under 35 U.S.C. § 119(a) to Korean application number 10-2008-0043023, filed on May 8, 2008, in the Korean Intellectual Property Office, which is incorporated herein by reference in its entirety as if set forth in full.

### BACKGROUND

1. Technical Field

The embodiments described herein relate to a delay locked loop circuit and relocking and a method for delay locking a signal.

2. Related Art

Conventional delay locked loop circuits detect phase differences between a system clock signal and an internal clock signal reflecting a delay value, and adjust a signal phase through a delay line including a unit delay cell having a predetermined delay time to feedback the adjusted phase, thereby tracking a phase difference until phase locking is achieved. The conventional delay locked loop circuit compensates for delay, which occurs in an input/output process of a clock signal, by a modeling value, then detects a phase difference between a feedback clock signal and a reference clock signal, and controls a delay factor to reduce the phase difference. However, in the operation of the delay locked loop circuit a negative delay effect can be caused by changing a delay value or distortion of a clock signal due to the environmental variations, such as voltage levels, temperature, pressure, and fabrication processing, in a semiconductor memory device. Furthermore, according to the delay locked loop circuit, a relatively long time is required until the phase locking is achieved, and a duty ratio may vary. Moreover, various noise and jitter may be generated when the phase of the clock signal is changed through a delay line, in which the delay value is determined through a plurality of delay cells and a replica delay for compensating for delay occurring in a clock signal input/output path.

As the semiconductor memory device operates at a high speed by receiving a clock signal having a high frequency, an extended time period is required until the phase locking is achieved, and a duty ratio may vary due to disadvantages of the conventional delay locked loop circuit. In addition, since noise and jitter characteristics deteriorate the clock signal, a new delay locked loop circuit is required in order to overcome such problems.

### SUMMARY

A delay locked loop circuit capable of quickly performing locking and relocking, and improving noise and jitter characteristics and a method for delay locking a signal are described herein.

In one aspect, a delay locked loop circuit includes a phase detecting unit for detecting a phase difference between a reference clock signal and a feedback clock signal, and for producing a phase difference detection signal, a code generating unit for producing a digital code signal according to the phase difference detection signal, a control current generating unit for generating a control current using the digital code signal, and a current controlled delay line for producing the feedback clock signal by delaying the reference clock signal by a delay time varied by the control current.

In another aspect, a method for delay locking a signal includes increasing or decreasing a value of a digital code signal according to a phase difference between a reference clock signal and a feedback clock signal, converting the digital code signal into a current, and generating the feedback clock signal by delaying the reference clock signal by varying a delay time depending on the current.

These and other features, aspects, and embodiments are described below in the section “Detailed Description.”

### BRIEF DESCRIPTION OF THE DRAWINGS

Features, aspects, and embodiments are described in conjunction with the attached drawings, in which:

FIG. 1 is a schematic block diagram of an exemplary delay locked loop circuit according to one embodiment; and

FIG. 2 is a schematic circuit diagram of an exemplary current controlled delay line capable of being implemented in the circuit of FIG. 1 according to one embodiment.

### DETAILED DESCRIPTION

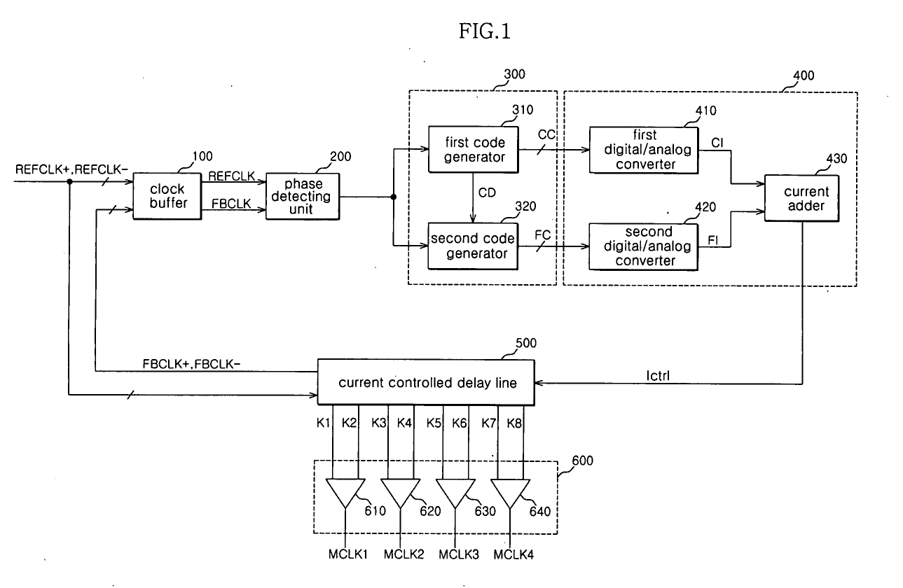

FIG. 1 is a schematic block diagram of an exemplary delay locked loop circuit according to one embodiment. In FIG. 1, an exemplary operation of a delay locked loop circuit can include a delay locking operation in first and second adjustment modes. For example, the first adjustment mode can be a coarse adjustment mode in which the delay locking operation can be performed by coarsely varying delay time of a current controlled delay line 500. Similarly, the second adjustment mode can be a fine adjustment mode in which the delay locking operation can be performed by finely varying the delay time of the current controlled delay line 500.

In FIG. 1, the delay locked loop circuit can be configured to include a clock buffer 100, a phase detecting unit 200, a code generating unit 300, a control current generating unit 400, the current controlled delay line 500, and a multi-phase clock generating unit 600.

The clock buffer 100 can convert potential levels of differential reference clock signals ‘REFCLK⁺’ and ‘REFCLK⁻’ and differential feedback clock signals ‘FBCLK⁺’ and ‘FBCLK⁻’ to CMOS levels, thereby producing a reference clock signal ‘REFCLK’ and a feedback clock signal ‘FBCLK’.

The phase detecting unit 200 can detect a phase difference between the reference clock signal ‘REFCLK’ and the feedback clock signal ‘FBCLK’ to produce a phase difference detection signal.

The code generating unit 300 can generate digital code signals, i.e. a first code signal ‘CC’ (Coarse Code) for the coarse adjustment mode and a second code signal ‘FC’ (Fine Code) for the fine adjustment mode, according to the phase difference detection signal. The code generating unit 300 can include a first code generator 310 and a second code generator 320. The first code generator 310 can increase or decrease the first code signal ‘CC’ according to the phase difference detection signal in the coarse adjustment mode. The first code generator 310 can activate a coarse adjustment mode end signal ‘CD’ if the coarse adjustment mode ends. The first code generator 310 can also determine an end of the coarse adjustment mode by detecting that the phase difference detection signal repeatedly has a level, i.e., high level, requiring an increase of the first code signal ‘CC’ and a level, i.e., low level, requiring a reduction of the first code signal ‘CC’.

The second code generator 320 can determine a start of the fine adjustment mode according to activation of the coarse adjustment mode end signal ‘CD’, and can increase or decrease the second code signal ‘FC’ according to the phase difference detection signal. The second code generator 320 can also determine an end of the fine adjustment mode by detecting that the phase difference detection signal repeatedly has a level, i.e., high level, requiring increase of the second code signal ‘FC’ and a level, i.e., low level, requiring a reduction of the second code signal ‘FC’.

The first and second code generators 310 and 320 can be prepared in the form of a finite-state machine for use in digital control in semiconductor integrated circuit (IC) devices.

The control current generating unit 400 can generate control current I_{ctrl} using the first and second code signals ‘CC’ and ‘FC’. In addition, the control current generating unit 400 can be configured to include a first digital/analog converter 410, a second digital/analog converter 420, and a current adder 430.

The first digital/analog converter 410 can convert the first code signal ‘CC’ into a first current signal ‘CI’. For example, the first digital/analog converter 410 can convert the first code signal ‘CC’ into a voltage, and then can convert the voltage into the first current signal ‘CI’ through a voltage/current converter provided therein.

The second digital/analog converter 420 can convert the second code signal ‘FC’ into a second current FI. For example, the second digital/analog converter 420 can convert the second code signal ‘FC’ into a voltage, and then can convert the voltage into the second current FI through the voltage/current converter provided therein.

The current adder 430 can add the first current CI and the second code signal ‘FC’ to produce the added current as the control current I_{ctrl}.

The current controlled delay line 500 can delay the differential reference clock signals ‘REFCLK⁺’ and ‘REFCLK⁻’ by a delay time varied by the control current I_{ctrl}, thereby producing the differential feedback clock signals ‘FBCLK⁺’ and ‘FBCLK⁻’. Furthermore, the current controlled delay line 500 can output multi-phase signals ‘K1’ to ‘K8’.

The multi-phase clock generating unit 600 can combine various signals, which can be out of phase with each other, of the multi-phase signals ‘K1’ to ‘K8’ to generate multi-phase clock signals ‘MCLK1’ to ‘MCLK4’.

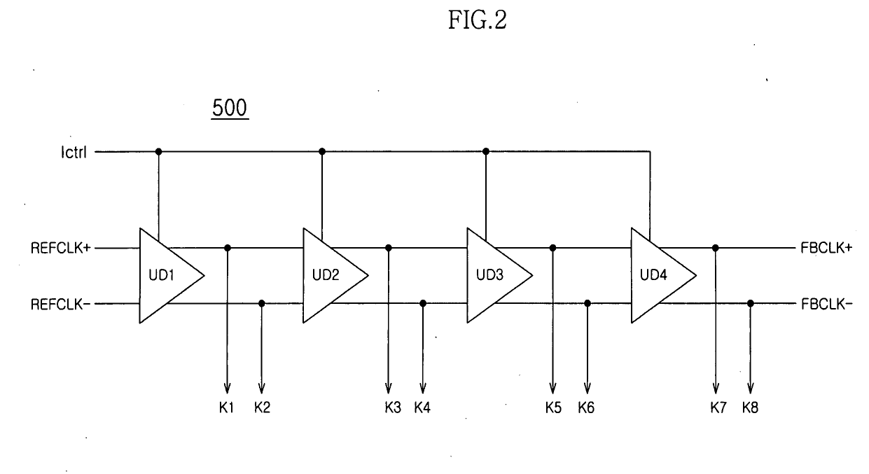

FIG. 2 is a schematic circuit diagram of an exemplary current controlled delay line capable of being implemented in the circuit of FIG. 1 according to one embodiment. In FIG. 2, the current controlled delay line 500 can include a plurality of delay units UD1 to UD4, each having a varying delay time depending on the control current I_{ctrl}. The delay unit UD1 to UD4 can be configured to operate in a current control scheme, for example.

The delay unit UD1 can output the multi-phase signals ‘K1’ and ‘K2’, the delay unit UD2 can output the multi-phase signals ‘K3’ and ‘K4’, the delay unit UD3 can output the multi-phase signals ‘K5’ and ‘K6’, and the delay unit UD4 can output the multi-phase signals ‘K7’ and ‘K8’. In addition, differential signals output from the delay units UD1 to UD4 can be out of phase with each other.

Accordingly, the multi-phase clock generating unit 600 can combine the multi-phase signals ‘K1’ and ‘K2’, which can be out of phase with each other, of the multi-phase signals ‘K1’ to ‘K8’ to generate the multi-phase clock signals ‘MCLK1’ to ‘MCLK4’. After the delay locking operation is completed, the multi-phase clock signals ‘MCLK1’ to ‘MCLK4’ can be selectively used as delay locked clock signals of a semiconductor IC.

The current controlled delay line 500 can output the differential feedback clock signals ‘FBCLK⁺’ and ‘FBCLK⁻’ by delaying the differential reference clock signals ‘REFCLK⁺’ and ‘REFCLK⁻’. When using delay units having a single input terminal and a single output terminal, the current controlled delay line 500 can be configured to output the feedback clock signal ‘FBCLK’ by delaying the reference clock signal ‘REFCLK’. When the current controlled delay line 500 produces the feedback clock signal ‘FBCLK’ by delaying the reference clock signal ‘REFCLK’, the clock buffer 100 may not be necessary. In addition, it is possible to output the multi-phase clock signals ‘MCLK1’ to ‘MCLK4’ without using the multi-phase clock generating unit 600 by directly drawing signal lines from the current controlled delay line 500.

An exemplary method for delay locking a signal will be described with reference to FIGS. 1 and 2.

First, an execution process of the coarse adjustment mode will be described in which the first code generator 310 can output the first code CC as an initial set value. Then, the first digital/analog converter 410 can convert the first code signal ‘CC’ into the first current CI for output.

During the execution of the coarse adjustment mode, i.e. deactivation of the coarse adjustment mode end signal ‘CD’, the second code generator 320 can output the second code signal ‘FC’ as an initial set value regardless of the phase difference detection signal.

Then, the second digital/analog converter 420 can convert the second code signal ‘FC’ into the second current FI for output. The current adder 430 can add the first current CI and the second code signal ‘FC’ to output the added current as the control current I_{ctrl}.

The delay units UD1 to UD4 of the current controlled delay line 500 can sequentially delay the differential reference clock signals ‘REFCLK⁺’ and ‘REFCLK⁻’ by a predetermined delay time according to the control current I_{ctrl}, thereby producing the differential feedback clock signals ‘FBCLK⁺’ and ‘FBCLK⁻’.

Next, the clock buffer 100 can buffer the differential reference clock signals ‘REFCLK⁺’ and ‘REFCLK⁻’ and the differential feedback clock signals ‘FBCLK⁺’ and ‘FBCLK⁻’ to output the reference clock signal ‘REFCLK’ and the feedback clock signal ‘FBCLK’.

The phase detecting unit 200 can output the phase difference detection signal at a high or low level according to whether the feedback clock signal ‘FBCLK’ has an advanced phase, as compared to the reference clock signal ‘REFCLK’. When the phase difference detection signal is at a first level, i.e., high level, the first code generator 310 can increase a code value of the first code signal ‘CC’ to output the first code signal ‘CC’. However, when the phase difference detection signal is at a level opposite to the first level, i.e., low level, the first code generator 310 can reduce (or decrease) the code value of the first code signal ‘CC’ to output the first code signal ‘CC’.

As the code value of the first code signal ‘CC’ is increased or reduced, the control current I_{ctrl} can be increased or reduced. Accordingly, the entire delay time of the current controlled delay line 500 can be increased or decreased.

If the coarse adjustment operation is repeated so that the phase difference between the reference clock signal ‘REFCLK’ and the feedback clock signal ‘FBCLK’ is within the range of unit increment of the entire delay time of the current controlled delay line 500, then the first code generator 310 can activate the coarse adjustment mode end signal ‘CD’.

If the phase difference between the reference clock signal ‘REFCLK’ and the feedback clock signal ‘FBCLK’ is within the range of the unit increment of the entire delay time of the current controlled delay line 500, the coarse adjustment operation can be completed. The unit increment of the entire delay time can represent variations in the entire delay time of the current controlled delay line 500, which can vary depending on an increase or decrease in a basic unit value of the first code signal ‘CC’.

Second, an execution process of the fine adjustment mode will be described in which, as the coarse adjustment mode end signal ‘CD’ is activated and the fine adjustment mode is executed, the first code generator 310 can output the first code signal ‘CC’ as a value finally set when the coarse adjustment mode ends regardless of the phase difference detection signal. As the coarse adjustment mode end signal ‘CD’ is activated and the fine adjustment mode is executed, the second code generator 320 can increase or decrease the second code signal ‘FC’ for output according to the phase difference detection signal.

Next, remaining operations can be similar to that of the coarse adjustment mode, except that the second code signal ‘FC’ can vary as the fine adjustment mode is executed and the first code signal ‘CC’ has the value that is finally set when the coarse adjustment mode ends.

If the fine adjustment operation is repeated so that the phase difference between the reference clock signal ‘REFCLK’ and the feedback clock signal ‘FBCLK’ is within the range of the unit increment of the entire delay time of the current controlled delay line 500, then the fine adjustment operation can be completed. The unit increment of the entire delay time can represent variations in the entire delay time of the current controlled delay line 500, which can vary depending on an increase or decrease in a basic unit value of the second code signal ‘FC’.

After the delay locking is achieved according to completion of the coarse adjustment operation and the fine adjustment operation, as detailed above, the multi-phase clock signals ‘MCLK1’ to ‘MCLK4’ output from the multi-phase clock generating unit 600 can be selectively used as delay locked clock signals of a semiconductor IC. While certain embodiments have been described above, it will be understood that the embodiments described are by way of example only. Accordingly, the device and method described herein should not be limited based on the described embodiments. Rather, the devices and methods described herein should only be limited in light of the claims that follow when taken in conjunction with the above description and accompanying drawings.

What is claimed is:

1. A delay locked loop circuit, comprising:
a phase detecting unit for detecting a phase difference between a reference clock signal and a feedback clock signal, and for producing a phase difference detection signal;
a code generating unit for producing a digital code signal according to the phase difference detection signal;
a control current generating unit for generating a control current using the digital code signal; and
a current controlled delay line for producing the feedback clock signal by delaying the reference clock signal by a delay time varied by the control current.

2. The delay locked loop circuit of claim 1, wherein the code generating unit includes a finite state machine that increases or decreases the digital code signal according to the phase difference detection signal, and outputs the digital code signal.

3. The delay locked loop circuit of claim 1, wherein the control current generating unit includes a digital/analog converter that converts the digital code signal into current to generate the control current.

4. The delay locked loop circuit of claim 1, wherein the current controlled delay line includes a plurality of delay units, each having a varying delay time depending on the control current.

5. The delay locked loop circuit of claim 1, wherein the code generating unit includes:
a first code generator for increasing or decreasing a first code signal according to the phase difference detection signal and for producing the first code signal; and
a second code generator for increasing or decreasing a second code signal according to the phase difference detection signal and for producing the second code signal.

6. The delay locked loop circuit of claim 5, wherein the first code generator is configured to determine completion of a first adjustment mode according to the phase difference detection signal and to activate a first adjustment mode end signal.

7. The delay locked loop circuit of claim 6, wherein the second code generator is configured to determine start of a second adjustment mode according to activation of the first adjustment mode end signal and to start a fine adjustment operation.

8. The delay locked loop circuit of claim 5, wherein the control current generating unit includes:
a first digital/analog converter for converting the first code signal into a first current;
a second digital/analog converter for converting the second code signal into a second current; and
a current adder for generating the control current by adding the first current and the second current.

9. The delay locked loop circuit of claim 4, wherein the current controlled delay line is configured to output multi-phase clock signals from output terminals of the delay units.

10. The delay locked loop circuit of claim 1, further comprising a clock buffer for producing the reference clock signal by buffering a first differential clock signal, and producing the feedback clock signal by buffering a second differential clock signal.

11. The delay locked loop circuit of claim 10, wherein the current controlled delay line includes a plurality of delay units to output the second differential clock signal by delaying the first differential clock signal by the varying delay time depending on the control current.

12. The delay locked loop circuit of claim 11, further comprising a multi-phase clock generating unit for producing multi-phase clock signals by combining output signals of the delay units.

13. A method for delay locking a signal, comprising:
increasing or decreasing a value of a digital code signal according to a phase difference between a reference clock signal and a feedback clock signal;
converting the digital code signal into a current; and
generating the feedback clock signal by delaying the reference clock signal by varying a delay time depending on the current.

14. The method of claim 13, wherein the increasing or decreasing of the value of the digital code signal includes:
increasing or decreasing a value of a first code signal according to a phase difference between the reference clock signal and the feedback clock signal in a first adjustment mode; and
increasing or decreasing a value of a second code signal according to the phase difference between the reference clock signal and the feedback clock signal in a second adjustment mode.

15. The method of claim 14, wherein unit increment of the delay time based on unit increment of the first code signal is larger than unit increment of the delay time based on unit increment of the second code signal.

16. The method of claim 14, wherein the first adjustment mode ends if the phase difference between the reference clock signal and the feedback clock signal, which is varied depending on an increase or decrease in the value of the first code signal, is less than a preset value.

17. The method of claim 14, wherein the second adjustment mode ends if the phase difference between the reference clock signal and the feedback clock signal, which is varied depending on an increase or decrease in the value of the second code signal, is less than a preset value.

18. The method of claim 14, wherein the second adjustment mode starts after the first adjustment mode ends.
